(19) United States
(12) Patent Application Publication
(10) Pub. No.: US 2025/0293152 A1
(43) Pub. Date: Sep. 18, 2025

(54) VERTICAL JFET SEMICONDUCTOR DEVICES WITH AVALANCHE CURRENT BALLAST RESISTANCE

(71) Applicant: Wolfspeed, Inc., Durham, NC (US)

(72) Inventor: Rahul R. Potera, Apex, NC (US)

(21) Appl. No.: 18/607,711

(22) Filed: Mar. 18, 2024

(51) Int. Cl. H01L 23/522; H01L 23/528; H01L 29/423; H01L 29/78

(52) U.S. Cl. CPC H01L 23/5228; H01L 23/5286; H10D 30/615; H10D 64/513

(57) ABSTRACT

A semiconductor device includes a semiconductor layer structure that includes an active region including a plurality of gate trenches, a plurality of gate contacts in respective ones of the gate trenches, a gate pad on the semiconductor layer structure, a gate bus extending from the gate pad, and a conductive path between the gate bus and a first one of the plurality of gate contacts. The conductive path includes a first resistivity region and at least one second resistivity region that has a higher resistivity than the first resistivity region.

### FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A semiconductor device according to some embodiments includes a semiconductor layer structure that includes an active region including a plurality of gate trenches, a plurality of gate contacts in respective ones of the gate trenches, a gate pad on the semiconductor layer structure, a gate bus extending from the gate pad, and a conductive path between the gate bus and a first one of the plurality of gate contacts. The conductive path includes a first resistivity region and at least one second resistivity region that has a higher resistivity than the first resistivity region.

The second resistivity region may not affect a resistance of a conductive path between the gate bus and a second one of the plurality of gate contacts.

The semiconductor device may further include a third resistivity region in an electrical path between the gate bus and a second one of the plurality of gate contacts, wherein the third resistivity region has a higher resistivity than the first resistivity region.

The semiconductor device may further include a silicide layer on the semiconductor layer structure, wherein the silicide layer forms the plurality of gate contacts and the conductive path between the gate contacts and the gate bus.

The second resistivity region may include a region of high sheet resistance in the silicide layer between the gate bus and the at least one of the gate trenches.

The second resistivity region may include a portion of the semiconductor layer structure on which the silicide layer is blocked from being formed in a silicidation process.

The second resistivity region may include a portion of the silicide layer having an increased resistance relative to a remainder of the silicide layer.

The conductive path may include a silicide block region between the gate bus and the at least one of the gate trenches that is devoid of the silicide layer.

The semiconductor device may further include a silicide block region adjacent each gate trench. In some embodiments, the semiconductor device may include one silicide block region adjacent multiple gate trenches.

The silicide block region may create negative feedback between a rising unclamped inductive switching (UIS) current in the semiconductor device and falling voltage across a gate-drain junction of the gate trench adjacent the gate resistance.

The negative feedback between rising UIS current and falling voltage across the gate-drain junction may cause avalanche current to be preferentially steered away from the first one of the plurality of gate contacts and toward a second one of the plurality of gate contacts.

The silicide block region may have a sheet resistance greater than about 10 kohms/square, in some embodiments a sheet resistance greater than about 20 kohms/square, and in some embodiments a sheet resistance of about 30 kohms/square.

The silicide block region may have a sheet resistance greater than 1000 times a sheet resistance of a silicide layer that forms the gate contacts, and in some embodiments the silicide block region has a sheet resistance greater than 10,000 times a sheet resistance of a silicide layer that forms the gate contacts.

The gate trenches include first end portions and second end portions, wherein the gate bus includes a first gate bus adjacent the first end portions, and the semiconductor device includes a first plurality of second resistivity regions in electrical paths between the first gate bus and respective ones of the gate trenches, a second gate bus extending from the gate pad adjacent the second end portions of the gate trenches, and a second plurality of second resistivity regions in electrical paths between the second gate bus and respective second end portions of the gate trenches.

The semiconductor device may further include a silicide layer on the semiconductor layer structure, wherein the silicide layer forms the plurality of gate contacts, and wherein the wherein the first gate bus and second gate bus are electrically connected to the plurality of gate contacts by the silicide layer.

The silicide block region may include a region of high sheet resistance that is about 1 to about 2 microns long in a direction of current flow from the gate bus to the respective gate trench.

The second resistivity region may include a region of high sheet resistance that is between about 1 and about 20 microns wide in a direction transverse to a direction of current flow from the gate bus to the respective gate trench.

The semiconductor device may include a JFET having a JFET gate terminal, a JFET source terminal and a JFET drain terminal.

The semiconductor device may further include a plurality of mesa stripes adjacent respective ones of the gate trenches.

A junction field effect transistor according to some embodiments includes a semiconductor layer structure, a gate pad on the semiconductor layer structure, a gate bus on the semiconductor layer structure, the gate bus electrically connected to the gate pad, and a plurality of gate contacts on and/or within the semiconductor layer structure that are electrically connected to the gate bus through a conductive interconnection region. The conductive interconnection region includes a plurality of first resistivity regions and a plurality of second resistivity region that have a sheet resistance at least ten times greater than a sheet resistance of the first regions.

A semiconductor device according to some embodiments includes a semiconductor layer structure that includes an active region including a plurality of gate trenches, a plurality of gate contacts in respective ones of the gate trenches, a gate pad on the semiconductor layer structure, a gate bus extending from the gate pad, and a conductive interconnection region in an electrical path between the gate bus and the plurality of gate contacts. The conductive interconnection region includes a plurality of current steering structures that define a plurality of channels therebetween.

### BRIEF DESCRIPTION OF DRAWINGS

FIG. 1 illustrates a cell of a vertical JFET semiconductor device.

FIG. 2 illustrates, in plan view, conventional layouts of vertical JFET semiconductor devices.

FIG. 3 is a circuit diagram of cells of a conventional vertical JFET semiconductor device under avalanche current conditions.

FIG. 4 is a circuit diagram of cells of a vertical JFET semiconductor device according to some embodiments.

FIG. 5A is a schematic plan view of a vertical JFET semiconductor device according to some embodiments.

FIG. 5B is a detail of a portion of the vertical JFET semiconductor device shown in FIG. 5A.

FIGS. 5C-5D are schematic cross-sectional diagrams taken along lines B-B, C-C and D-D of FIG. 5A, respectively.

FIG. 5E is a cross-sectional view of a single mesa and adjacent trenches of a vertical JFET according to some embodiments.

FIGS. 6-9 are schematic plan views of vertical JFET semiconductor devices according to further embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

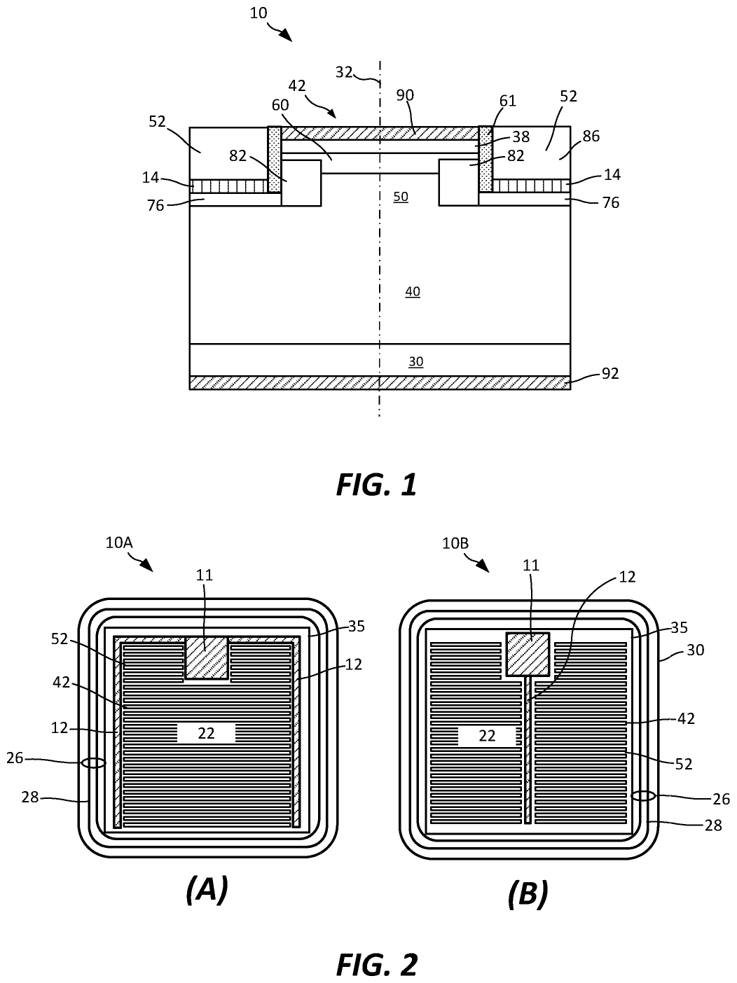

An n-channel vertical JFET structure 10 is shown in FIG. 1. The vertical JFET structure 1 includes an n+ substrate 30 on which an n− drift layer 40 is formed. An n-type channel region 50 is on the drift layer 40, and an n+ source layer 60 is on the channel region 50. An n++ source contact layer 38 is on the n+ source layer 60. A drain ohmic contact 92 is on the substrate 30, and a source ohmic contact 90 is on the source contact layer 38. The channel region 50, source layer 60 and source contact layer 38 are provided as part of a mesa 42 above the drift layer 40. Trenches 52 are formed in the structure 10 adjacent the mesa 42.

A p+ gate region 82 is provided as part of the mesa 42 adjacent the channel region 50. A p++ gate contact region 76 is provided adjacent the gate region 82, and a gate ohmic contact 14 is formed on the gate contact region 76 in the trenches 52 on opposite sides of the mesa 42. To form the gate ohmic contact 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate ohmic contact 14 and the gate contact region 76. The insulation layer 86 may be formed from silicon oxide. Silicon nitride spacer layers 61 are provided on sidewalls of the mesa 42.

The vertical JFET unit cell structure 10 is symmetrical about the axis 32 and includes two gate regions 82 as part of the mesa 42 on opposite sides of the channel region 50.

The channel of the vertical JFET structure 10 is formed within the mesa 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30.

FIG. 2 illustrates, in plan view, conventional layouts of vertical JFET semiconductor devices 10A and 10B. Referring to FIG. 2(A), a JFET device 10A is formed on a substrate 30. The device 10A includes an active region 22 in which a plurality of alternating mesas 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A silicide region 35 is formed on an upper surface of the device within the active region 22 in areas other than on the mesas 42. The silicide region 35 forms the gate ohmic contacts 14 within the trenches 52. A gate contact pad 11 is formed on the upper surface of the device 10A within the silicide region 35, and a pair of gate buses 12 (also referred to as gate runners 12) extend from the gate contact pad 11 around the outer periphery of the active region 22 adjacent the ends of the mesas 42 and trenches 52 of the device 10A. The gate contact pad 11 and the gate buses 12 may include a conductive material such as a metal silicide and/or a metal layer.

The silicide region 35 provides a low resistance current path between the gate buses 12/gate contact pad 11 and the gate ohmic contacts 14 (FIG. 1) that are formed within the trenches 52.

The JFET device 10B shown in FIG. 2(B) is similar to the JFET device 10A shown in FIG. 2(A), except that the JFET device 10B includes only a single gate bus 12 which extends from the gate contact pad 11 through the center of the active region 22.

In both JFET devices 10A, 10B, a gate voltage applied to the gate contact pad 11 is conducted through the gate bus 12 and silicide region 35 to the gate ohmic contacts 14 within the trenches 52.

In a switching power device such as a JFET device, a phenomenon referred to as unclamped inductive switching (UIS) may occur when the device is placed under high reverse bias. UIS occurs when current undesirably flows from the drain of the device back through the gate of the device. This subjects the device simultaneously to high current and high voltage, which dissipates a high amount of power in the device and may cause the device to fail when the UIS current exceeds a threshold limit. The ability to handle UIS current is an important quality of a switching power device.

If UIS current is limited by current crowding and filamentation in a part of the semiconductor structure, UIS weakness can be addressed by making the junction breakdown more uniform so that heat is dissipated more uniformly across the device. If UIS current is limited by the current carrying regions outside the semiconductor device, UIS weakness can be addressed by increasing ampacity at those choke points.

When UIS current is not limited in those ways, then gate-drain UIS current causes a voltage drop across the gate resistance, which biases the gate of the device. At sufficient UIS current, this UIS-induced gate bias can exceed the local threshold voltage (VT) of the device and turn on the channel locally (i.e., in the vicinity of the induced gate bias). The channel current induced by UIS biasing will heat up the device locally creating a hotspot in the device. This further reduces VT and increases leakage near the hotspot. This condition creates a positive feedback loop, referred to as a thermal runaway condition, that can cause the device to fail catastrophically at the hotspot.

Some embodiments described herein provide UIS gate current ballasting structures that may slow down positive feedback and hotspotting under UIS conditions, which may increase the UIS handling capability of the JFET.

As described above, in a vertical power semiconductor device such as a JFET device, a gate bus feeds a gate signal to the gate trenches at the ends of the source mesas. The gate trenches are silicided and designed to achieve the lowest possible gate resistance. In conventional designs, if UIS current starts flowing within a particular gate trench, positive feedback between rising temperature and lowering VT can cause a hotspot to be formed at that trench.

Some embodiments provide localized gate resistances that may ballast UIS current and create negative feedback between rising UIS current and falling voltage across gate-drain junction of that gate trench so that UIS shifts to nearby gate trenches where voltage across gate-drain junction is still higher.

In some embodiments, the localized gate resistances may be provided by silicide block regions, which are regions within the silicide region of a device where the silicide is blocked from being formed. That is, silicide block regions are regions on the surface of the device that are intentionally formed to be free of silicide. The silicide block regions may be formed near the ends of the gate trenches.

In silicide block regions, current is selectively forced to travel through the semiconductor layers of the device, which may have significantly higher sheet resistance than silicide and/or through narrower silicide regions that may have higher resistance. For example, silicide block regions may have sheet resistance of about 30 kohms/sq, which is about 10,000 times higher than the sheet resistance of silicided regions (which have a sheet resistance of about 3-4 ohms/sq).

The introduction of such local gate resistances causes the silicided gate resistance at ends of gate trenches to be significantly higher than the silicided gate resistance inside trenches.

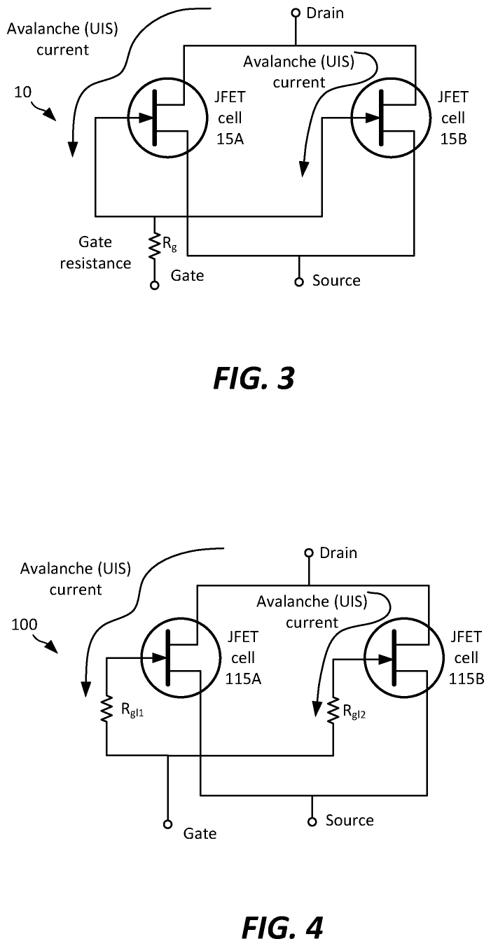

FIG. 3 shows an example circuit showing gate current flowing through two JFET elements, or cells, 15A, 15B of a conventional JFET device 10 under UIS conditions. The device shown in FIG. 3 includes a gate resistance Rg that could be externally added and shared between the cells 15A, 15B. FIG. 4 shows two JFET cells 115A, 115B of a JFET device 100 according to some embodiments. As will be appreciated, the JFET device 100 will typically include many more JFET cells than illustrated in FIG. 4. The cells 115A, 115B of the JFET device 100 are connected in parallel, and each has a local gate resistance R_{g11}, R_{g12} connected to its gate. When UIS current flows through one of the JFET cells 115A, 115B, the UIS current biases the gate so that gate-drain bias of that JFET cell 115A, 115B is reduced compared to the other JFET cell 115A, 115B. This causes the UIS condition to shift to the other JFET cell 115A, 115B. In this way, UIS avalanche current can be shared or spread between the two JFET cells 115A, 115B until the gate of any one JFET cell has biased up enough to turn on the channel and cause UIS failure. UIS failure in the device of FIG. 4 may therefore happen at a higher current/energy than it otherwise would because of the presence of the local gate resistances R_{gf1}, R_{gf2}. In contrast, in the device 10 of FIG. 3, UIS current flowing through one JFET cell 15A, 15B does not bias up the gate of only that JFET cell, and so does not ballast UIS current.

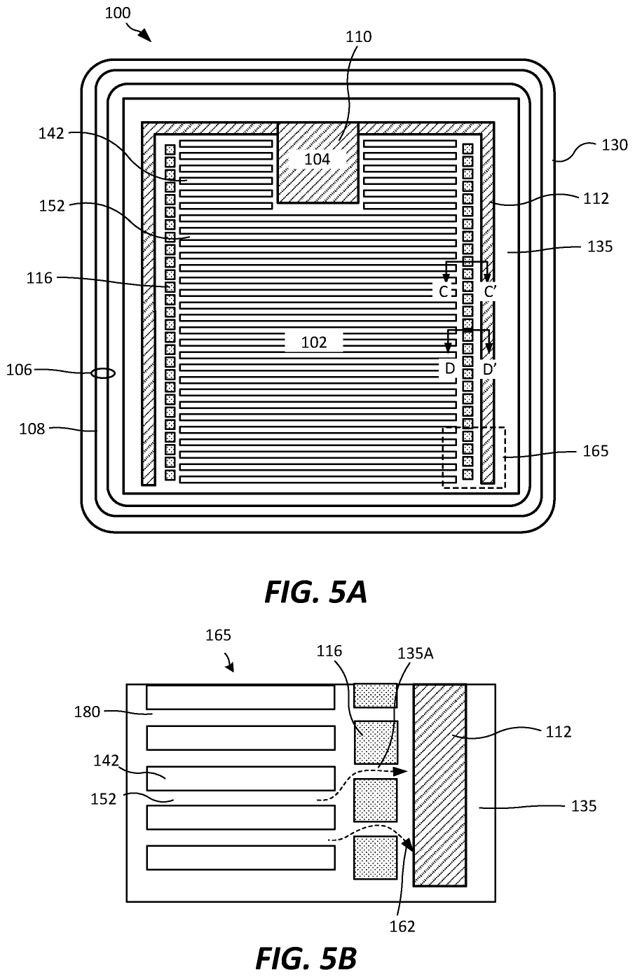

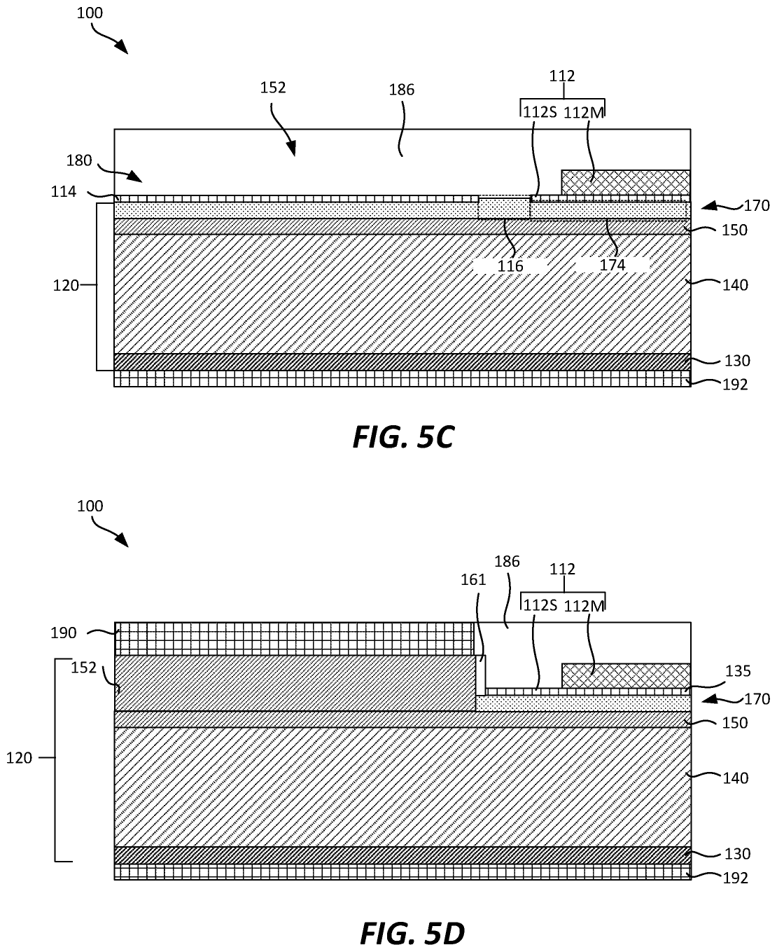

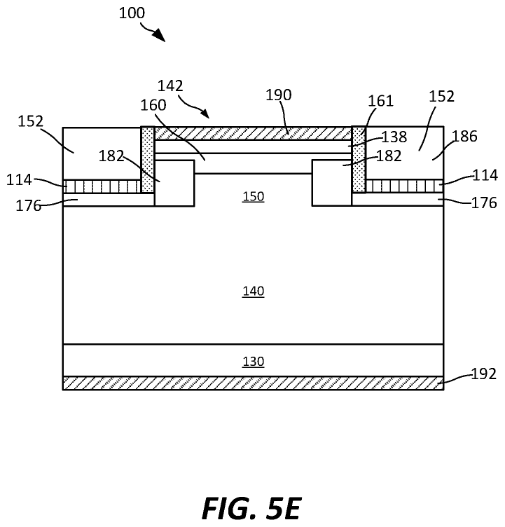

FIG. 5A is a schematic plan view of a vertical JFET 100 according to some embodiments. In FIG. 5A, several of the upper layers of the JFET 100 including the source bond pads, the source contacts, the gate insulating patterns and the upper passivation/protection patterns are omitted to better show the gate structure of the vertical JFET 100. FIG. 5B is a detail of a portion 165 of the vertical JFET semiconductor device shown in FIG. 5A, and FIGS. 5C-5D are schematic cross-sectional diagrams taken along lines C-C and D-D of FIG. 5A, respectively. FIG. 5E is a cross-sectional view of a single mesa 142 and adjacent trenches 152 of a vertical JFET 100. To provide additional context, the source contact 190 and the gate insulating patterns 186 that are omitted in FIG. 5A are shown in FIGS. 5C, 5D and/or 5E, although the other layers discussed above are still omitted in FIGS. 5C-5D.

Referring to FIGS. 5A and 5E, the vertical JFET 100 includes an active region 102, a gate pad/gate bus region 104, and a termination region 106. The active region 102 is the portion of the vertical JFET 100 that acts as a main junction for blocking voltage during off-state operation and current flows through the active region 102 during on-state operation. The active region 102 includes a plurality of alternating mesas 142 and trenches 152 therein.

A metal silicide region 135 is formed on portions of the active region 102 other than mesas 142.

The vertical JFET 100 may have a unit cell structure such that a large number of individual “unit cell” JFETs are formed in the active region 102 and electrically connected in parallel to each other so that the unit cells together function as a single vertical JFET 100. The gate pad/gate bus region 104 is the region corresponding to a gate pad 110 and a gate bus 112. The gate pad 110 may comprise a metal pad and may be provided underneath a gate bond pad (not shown) if a separate gate bond pad is provided. The gate bond pad (or the gate pad 110 if no gate bond pad is provided) may be connected to an external circuit through bond wires, leads or other electrical connections.

The gate pad 110 provides an electrical connection between the gate bond pad (or the external circuit) and the gate bus 112. The gate bus 112 may be a high conductivity bus that carries gate signals from the gate pad 110 to a plurality of gate ohmic contacts 114 that are provided in trenches 152 in the active region 102. A gate ohmic contact 114 in a particular trench 152 may be referred to herein as a “gate finger” due to its elongated shape. Accordingly, the JFET device 100 includes a plurality of gate fingers 114 in respective trenches 152. The terms “gate finger” and “gate ohmic contact” are used interchangeably herein. The metal silicide region 135 forms an interconnection region between the gate bus 112 and the gate ohmic contacts 114 in the trenches 152.

The gate ohmic contacts 114 feed a plurality of gate regions 182 that are in the active region 102. The gate ohmic contacts 114 may, for example, be within the bottom surfaces and/or side surfaces of the respective gate trenches 152. In some embodiments, metal gate electrodes (not shown) may be formed on the gate ohmic contacts 114 to promote current spreading along the gate contacts 114 and to reduced gate resistance. However, such electrodes may be omitted, e.g., because it may be difficult to form metal contacts within narrow gate trenches. As shown in FIG. 5A, the gate pad 110 and the gate bus 112 may be formed as a single integral (monolithic) pattern.

The edge termination region 106 is a region that at least partially surrounds the active region 102 and the gate pad/gate bus region 104. The edge termination region 106 is designed to spread the electric fields during reverse blocking operation out over a greater area in order to reduce electric field crowding effects that would otherwise occur along the outer edges of the active region 102. An ellipse labelled 106 in FIG. 5A identifies a small portion of the termination region 106, but it will be appreciated that the termination region 106 extends all of the way around the gate pad/gate bus region 104.

Referring to FIGS. 5C-5E, the vertical JFET 100 includes a semiconductor layer structure 120. The semiconductor layer structure 120 may include a substrate 130, a drift region 140, a channel region 150, and source regions 160.

The substrate 130 may be formed of wide bandgap semiconductor materials (e.g., may be a silicon carbide substrate) and may be heavily doped with n-type (n+) dopants in example embodiments. The substrate 130 may have a doping concentration of 1×10¹⁸ to 1×10²¹ dopants/cm³ in example embodiments. The drift region 140 may be provided on an upper surface of the substrate 130. The drift region 140 may be formed of wide bandgap semiconductor materials (e.g., may be an epitaxially grown silicon carbide layer) and may be a lightly-doped n-type (n−) region. The drift region 140 may have, for example, a doping concentration of 1×10¹⁴ to 1×10₁₇ dopants/cm³ in example embodiments. The drift region 140 may be a thick region, having a vertical height above the substrate 130 of, for example, 3-100 microns. While not shown in FIGS. 5C-5E, in some embodiments an upper portion of the drift region 140 may be more heavily doped (e.g., a doping concentration of 1×10¹⁶ to 2×10¹⁷ dopants/cm³) than the lower portion thereof to provide a current spreading layer in the upper portion of the drift region 140.

The channel region 150 is provided on an upper surface of the drift region 140. The channel region 150 may be formed of wide bandgap semiconductor materials (e.g., epitaxially grown silicon carbide) and may be a moderately doped n-type (n) region. The channel region 150 may have a doping concentration higher than the doping concentration of the lower portion of the drift region 140. For example, a doping concentration of the channel region 150 may be between 1×10¹⁶ to 1×10¹⁷ dopants/cm³.

The source regions 160 may be provided on an upper surface of the channel region 150. The source regions 160 may be formed of wide bandgap semiconductor materials (e.g., epitaxially grown silicon carbide) and may be heavily-doped n-type (n+) regions. The source regions 160 may have a doping concentration higher than that of the channel region 150 and may have, for example, a doping concentration of 1×10¹⁹ to 5×10²⁰ dopants/cm³.

A plurality of trenches 152 are formed in the semiconductor layer structure 120 using, for example, one or more etching processes. The trenches 152 may be formed in the channel region 150 and the source regions 160 in the active region 102, the gate region 104 and the termination region 106.

A patterned region 170 between and around the mesas 142 may be formed of wide bandgap semiconductor materials (e.g., silicon carbide) and may be a heavily-doped p-type (p+) region. The patterned region 170 may be formed, for example, by implanting p-type dopants through the bottoms of the respective trenches 152 so as to convert selected portions of the channel region 150 into p-type semiconductor material. The patterned region 170 may have, for example, a doping concentration of 1×10¹⁹ to 5×10²⁰ dopants/cm³. The patterned region 170 may be a continuous region or a plurality of discontinuous regions. The portions of the patterned region 170 that are within the active region 102 may comprise the gate contact regions 176, as will be discussed in greater detail below.

The gate regions 182 in the mesas 142 may be formed of wide bandgap semiconductor materials (e.g., silicon carbide) and may be p-type regions. Gate contact regions 176 are provided at the bottoms of the trenches 152 and may have a high doping concentration, for example, a doping concentration of 1×10¹⁹ to 2×10²⁰ dopants/cm³. The gate regions 182 may have, for example, a doping concentration of 1×10¹⁷ to 1×10¹⁸ dopants/cm³, and may be formed, for example, by performing an angled ion implantation process to implant p-type dopants into the sidewalls of the trenches 152.

In some embodiments, the drift region 140, the channel region 150 and the source regions 160 may all be formed by one or more epitaxial growth processes using the substrate 130 as a seed layer. As discussed above, the patterned region 170 and the gate regions 180 may be formed by implanting p-type dopants into selected portions of the channel region 150.

The gate pad 110 and the gate bus 112 are provided on the semiconductor layer structure 120. The gate bus 112 may comprise a metal silicide gate bus region 112S and a metal gate bus 112M that likewise are sequentially stacked on the gate bus portion 174 of the patterned region 170. An upper surface of the gate bus portion 174 of the patterned region 170 may contact the metal silicide gate bus region 112S.

Each unit cell JFET in the active region 102 includes a gate ohmic contact 114. The gate ohmic contact 114 may include a metal silicide gate contact region and a metal gate contact (not shown) that are sequentially stacked on the gate contact regions 176 within the trenches 152.

As the drift region 140, the channel region 150 and the source regions 160 have the same conductivity type (e.g., n-type), each unit cell of the vertical JFET 100 is normally on and is turned off when a sufficient negative gate bias relative to the source region 160 is applied to the gate pad 110 or when the voltage at the JFET source region 160 is brought to a sufficiently high level relative to the gate region 182.

The gate pad 110, the metal silicide gate bus region 112S and the metal silicide gate ohmic contact regions 114 provide a very low resistance electrical path from the metal gate pad 110 to the gate contact regions 176. In provided, metal gate contacts (not shown) provide low resistivity paths above each gate contact region 176 so that the gate signal may spread throughout the active region 102 and then pass to the gate regions 182 along the lengths of the trenches 152. The metal silicide gate bus region 112S and the metal silicide gate ohmic contacts region 114 may be formed of metal silicide (e.g., nickel silicide, tungsten silicide, titanium silicide or molybdenum silicide). In some embodiments, the metal silicide gate bus region 112S and the metal silicide gate ohmic contacts 114 may be formed of nickel silicide.

The vertical JFET device 100 may also include gate insulating patterns 186 that are provided in the trenches 152. The gate insulating patterns 186 may comprise, for example, one or more dielectric materials such as silicon oxide, silicon nitride, silicon oxynitride or the like.

A source contact 190 may be provided on the source regions 160 and the gate insulating patterns 186. The source contact 190 may include one or more layers such as, for example, a diffusion barrier layer and a bulk metal layer. The gate insulating patterns 186 may isolate the gate bus 112M and the gate ohmic contacts 114 from the source contact 190.

A drain pad 192 (e.g., a metal drain pad) may be provided on the bottom side of the vertical JFET 100. The drain pad 192 may be connected to an underlying submount such as a lead frame, a heat sink, a power substrate or the like via soldering, brazing, direct compression or the like.

Referring to FIGS. 5A-5E, it can be seen that according to some embodiments of the present invention, semiconductor devices such as vertical JFET 100 are provided that include a semiconductor layer structure 120 that has an active region 102 and a termination region 106. The termination region 106 may at least partially surround the active region 102. The vertical JFET 100 further comprise a gate pad 110 and a gate bus that is electrically connected to the gate pad 110 on the semiconductor layer structure 120. The semiconductor device further comprises a plurality of gate contacts 114, as well as a silicide block region 116 that is interposed between the gate bus 112 and at least some of the gate contacts 114 when the vertical JFET 100 is viewed in plan view.

While the semiconductor devices discussed above are n-type devices, it will be appreciated that in p-type devices these locations are reversed and that this invention applies to both n-type and p-type devices. Moreover, while the above-described power semiconductor devices and the other devices described herein are shown as being silicon carbide-based semiconductor devices, it will be appreciated that embodiments of the present invention are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

FIG. 5B illustrates a detail of a portion 165 of the vertical JFET device 100 of FIG. 5A. As shown therein, a plurality of regions 116 of high sheet resistance are provided in the silicide region 135 to provide a local resistance R_{g1} to gate contacts 114 in the respective trenches 152. The regions 116 of high sheet resistance may be provided as silicide block regions 116 in some embodiments. That is, the regions 116 of high sheet resistance may be provided by selectively blocking the formation of silicide in predefined portions of the silicide region 135 near the trenches 152. For example, brief reference is made to FIG. 5C, which is a cross-sectional illustration showing a trench 152 and the gate bus 112. As shown therein, a region 116 adjacent the trench 152 is free of silicide.

The presence of the regions 116 provides an increased local resistance in a current path for UIS current 162 between the gate ohmic contacts 114 in the trenches 152 and the gate bus 112. That is, the UIS current may be preferentially steered by the regions 116 of high sheet resistance into channels defined by the narrower silicide regions 135A, which may increase the resistance of the current path for UIS current. As is known in the art, the resistance R of a conductive region of a given material is given by the formula:

R=ρl/A [1]

where ρ is the resistivity of the material, l is the length of the region, and A is the cross sectional area of the region. By reducing the width of the silicide regions 135A in the current path, the cross sectional area A of the current path is reduced, thereby increasing the resistance of the path.

Moreover, although the sheet resistance of the regions 116 is significantly greater than that of the silicide portions of the silicide region 135, the regions 116 may nevertheless conduct at least some portion of the UIS current though the doped semiconductor material in the patterned region 170. However, the effective sheet resistance of the UIS current path for a given gate finger is increased by the presence of the regions 116.

In some embodiments, the regions 116 are positioned adjacent the trenches 152. In other embodiments, the regions 116 may be positioned adjacent the mesas 142. The regions 116 may completely or partially overlap the trenches 152 and/or the mesas 142.

In some embodiments, the regions 16 may have dimensions of about 1.5 microns by 1.5 microns, which may add about 15 to 30 ohms of local resistance to each gate finger 114 depending on the configuration.

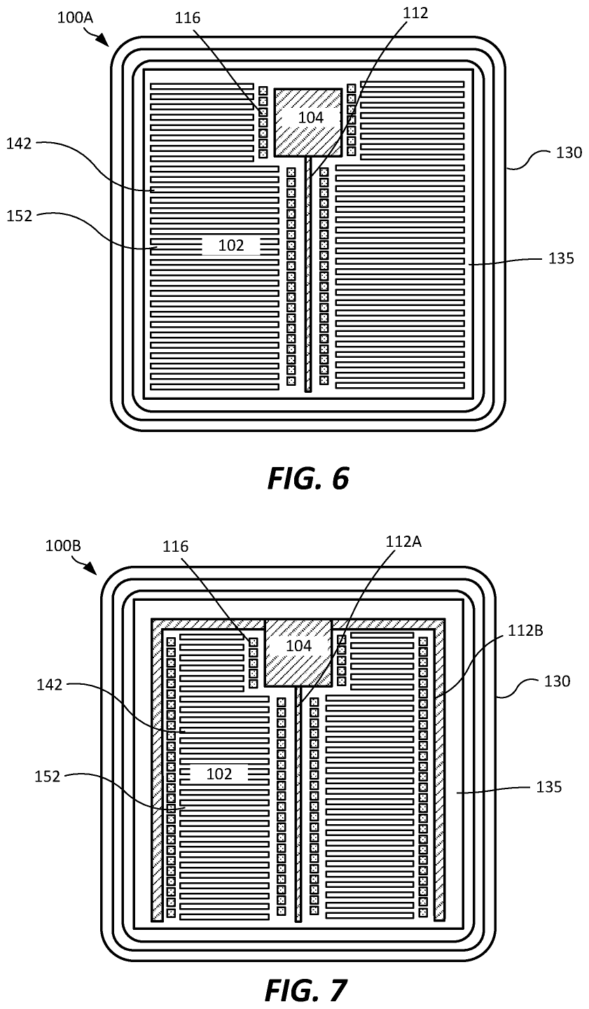

FIGS. 6-9 are schematic plan views of vertical JFET semiconductor devices according to further embodiments.

For example, FIG. 6 illustrates a plan view layout of a vertical JFET device 100A that includes a single gate bus 112 that divides the active region 102 into two sides. The regions 116 are provided between the gate bus 112 and inner ends of the trenches 152. In some embodiments, one region 116 may be provided adjacent each trench 152. In other embodiments, multiple regions 116 may be provided adjacent each trench 152, and in still further embodiments, one region 116 may be provided adjacent multiple trenches 152.

FIG. 7 illustrates a plan view layout of a vertical JFET device 100B that includes an inner gate bus 112A that divides the active region 102 into two sides and outer gate buses 112B that extend outside the mesas 142. The regions 116 are provided between the inner gate bus 112A and inner ends of the trenches 152 and between the outer gate buses 112B and outer ends of the trenches 152. In some embodiments, one region 116 may be provided adjacent each trench 152. In other embodiments, multiple regions 116 may be provided adjacent each trench 152, and in still further embodiments, one region 116 may be provided adjacent multiple trenches 152.

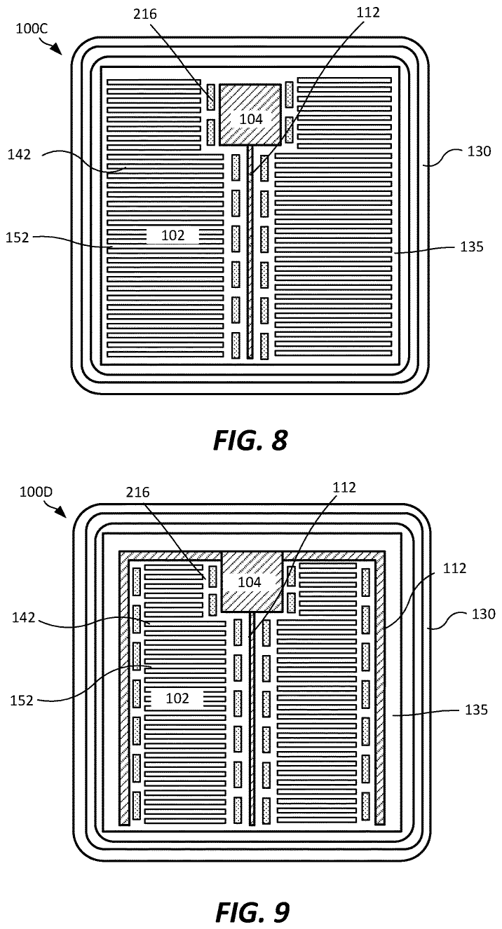

FIG. 8 illustrates a plan view layout of a vertical JFET device 100C that includes a single gate bus 112 that divides the active region 102 into two sides. The regions 116 are provided between the gate bus 112 and inner ends of the trenches 152. Regions 216 of high sheet resistance are provided between the gate bus 112 and inner ends of the trenches 152. Each region 216 is sized to overlap with multiple trenches 152.

FIG. 9 illustrates a plan view layout of a vertical JFET device 100D that includes an inner gate bus 112A that divides the active region 102 into two sides and outer gate buses 112B that extend outside the mesas 142. Regions 216 of high sheet resistance are provided between the inner gate bus 112A and inner ends of the trenches 152 and between the outer gate buses 112B and outer ends of the trenches 152. Regions 216 of high sheet resistance are provided between the gate bus 112 and inner ends of the trenches 152. Each region 216 is sized to overlap with multiple trenches 152.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure that comprises an active region including a plurality of gate trenches;
a plurality of gate contacts in respective ones of the gate trenches;
a gate pad on the semiconductor layer structure;
a gate bus extending from the gate pad; and
a conductive path between the gate bus and a first one of the plurality of gate contacts;
wherein the conductive path includes a first resistivity region and at least one second resistivity region that has a higher resistivity than the first resistivity region.

2. The semiconductor device of claim 1, wherein the second resistivity region does not affect a resistance of a conductive path between the gate bus and a second one of the plurality of gate contacts.

3. The semiconductor device of claim 2, further comprising a third resistivity region in an electrical path between the gate bus and a second one of the plurality of gate contacts, wherein the third resistivity region has a higher resistivity than the first resistivity region.

4. The semiconductor device of claim 1, further comprising a silicide layer on the semiconductor layer structure, wherein the silicide layer forms the plurality of gate contacts and the conductive path between the gate contacts and the gate bus.

5. The semiconductor device of claim 4, wherein the second resistivity region comprises a region of high sheet resistance in the silicide layer between the gate bus and the at least one of the gate trenches.

6. The semiconductor device of claim 4, wherein the second resistivity region comprises a portion of the semiconductor layer structure on which the silicide layer is blocked from being formed in a silicidation process.

7. The semiconductor device of claim 4, wherein the second resistivity region comprises a portion of the silicide layer having an increased resistance relative to a remainder of the silicide layer.

8. The semiconductor device of claim 4, wherein the conductive path comprises a silicide block region between the gate bus and the at least one of the gate trenches that is devoid of the silicide layer.

9. The semiconductor device of claim 8, wherein the semiconductor device comprises a silicide block region adjacent each gate trench.

10. The semiconductor device of claim 8, wherein the semiconductor device comprises one silicide block region adjacent multiple gate trenches.

11. The semiconductor device of claim 8, wherein the silicide block region creates negative feedback between a rising unclamped inductive switching (UIS) current in the semiconductor device and falling voltage across a gate-drain junction of the gate trench adjacent the gate resistance.

12. The semiconductor device of claim 11, wherein the negative feedback between rising UIS current and falling voltage across the gate-drain junction causes avalanche current to be preferentially steered away from the first one of the plurality of gate contacts and toward a second one of the plurality of gate contacts.

13. The semiconductor device of claim 8, wherein the silicide block region has a sheet resistance greater than about 10 kohms/square.

14. The semiconductor device of claim 8, wherein the silicide block region has a sheet resistance greater than about 20 kohms/square.

15. The semiconductor device of claim 8, wherein the silicide block region has a sheet resistance of about 30 kohms/square.

16. The semiconductor device of claim 8, wherein the silicide block region has a sheet resistance greater than 1000 times a sheet resistance of a silicide layer that forms the gate contacts.

17. The semiconductor device of claim 8, wherein the silicide block region has a sheet resistance greater than 10,000 times a sheet resistance of a silicide layer that forms the gate contacts.

18. The semiconductor device of claim 1, wherein the gate trenches comprise first end portions and second end portions, wherein the gate bus comprises a first gate bus adjacent the first end portions, the semiconductor device further comprising:
a first plurality of second resistivity regions in electrical paths between the first gate bus and respective ones of the gate trenches;
a second gate bus extending from the gate pad adjacent the second end portions of the gate trenches; and
a second plurality of second resistivity regions in electrical paths between the second gate bus and respective second end portions of the gate trenches.

19. The semiconductor device of claim 18, further comprising a silicide layer on the semiconductor layer structure, wherein the silicide layer forms the plurality of gate contacts, and wherein the wherein the first gate bus and second gate bus are electrically connected to the plurality of gate contacts by the silicide layer.

20. The semiconductor device of claim 8, wherein the silicide block region comprises a region of high sheet resistance that is about 1 to about 2 microns long in a direction of current flow from the gate bus to the respective gate trench.

21. The semiconductor device of claim 1, wherein the second resistivity region comprises a region of high sheet resistance that is between about 1 and about 20 microns wide in a direction transverse to a direction of current flow from the gate bus to the respective gate trench.

22. The semiconductor device of claim 1, wherein the semiconductor device comprises a junction field effect transistor (“JFET”) having a JFET gate terminal, a JFET source terminal and a JFET drain terminal.

23. The semiconductor device of claim 1, further comprising a plurality of mesa stripes adjacent respective ones of the gate trenches.

24. A junction field effect transistor, comprising:
a semiconductor layer structure;
a gate pad on the semiconductor layer structure;
a gate bus on the semiconductor layer structure, the gate bus electrically connected to the gate pad; and
a plurality of gate contacts on and/or within the semiconductor layer structure that are electrically connected to the gate bus through a conductive interconnection region, the conductive interconnection region including a plurality of first resistivity regions and a plurality of second resistivity region that have a sheet resistance at least ten times greater than a sheet resistance of the first regions.

25. A semiconductor device, comprising:
a semiconductor layer structure that comprises an active region including a plurality of gate trenches;
a plurality of gate contacts in respective ones of the gate trenches;
a gate pad on the semiconductor layer structure;
a gate bus extending from the gate pad; and
a conductive interconnection region in an electrical path between the gate bus and the plurality of gate contacts, wherein the conductive interconnection region includes a plurality of current steering structures that define a plurality of channels therebetween.
